(19) United States
(12) Patent Application Publication
(10) Pub. No.: US 2011/0195542 A1
(43) Pub. Date: Aug. 11, 2011

(54) METHOD OF PROVIDING SOLAR CELL ELECTRODE BY ELECTROLESS PLATING AND AN ACTIVATOR USED THEREIN

(75) Inventors: Chia Wei Chou, Ying-Go Town (TW); Su-Fei Hsu, Ying-Go Town (TW); Michael Liu, Ying-Go Town (TW)

(73) Assignee: E-CHEM ENTERPRISE CORP., Ying-Go Town (TW)

(21) Appl. No.: 13/013,884

(22) Filed: Jan. 26, 2011

Related U.S. Application Data
(60) Provisional application No. 61/282,420, filed on Feb. 5, 2010.

(51) Int. Cl. H01L 21/288; H01B 1/02; H01B 1/22

(52) U.S. Cl. 438/98; 252/514; 252/518.1; 252/520.3; 252/519.32; 252/519.33; 257/E21.174

(57) ABSTRACT

A method of providing solar cell electrode by electroless plating and an activator used therein are disclosed. The method of the present invention can be performed without silver paste, and comprises steps: (A) providing a silicon substrate; (B) contacting the silicon substrate with an activator, wherein the activator comprises: a noble metal or a noble metal compound, a thickening agent, and water; (C) washing the silicon substrate by a cleaning agent; (D) dipping the silicon substrate in an electroless nickel plating solution to perform electroless plating. The method of providing solar cell electrode by electroless plating of the present invention has high selectivity between silicon nitride and silicon, large working window, and is steady, easily to be controlled, therefore is suitable for being used in the fabrication of the electrodes of the solar cell substrate.

### CROSS REFERENCE TO RELATED APPLICATION

This application claims the benefit of filing date of U.S. Provisional Application Ser. No. 61/282,420, entitled “Electroless Nickel Plating Solution For Solar Cell Electrode And Method Using The Same” filed Feb. 5, 2010 under 35 USC §119(e)(1).

### BACKGROUND OF THE INVENTION

1. Field of the Invention

The present invention relates to a method of providing solar cell electrode by electroless nickel plating and an activator used therein and, more particularly, to a method of providing solar cell electrode by electroless nickel plating without using a silver paste, and an activator used therein.

2. Description of Related Art

With the development of industrial technology, the serious problems that the whole world is facing today are the energy crisis and the environmental pollution. In order to solve the global energy crisis and to reduce the environmental pollution, a lot of efforts are being made on green energy, such as wind power and solar energy, to replace fossil fuel sources. In particular, the solar cell is one of the effective means, which can convert the solar energy into electricity.

Reference with FIGS. 1A to 1C, a process flow chart of providing an electrode of a conventional solar cell is shown. First, a semi-product of silicon substrate 1 is provided, in which the silicon substrate 1 comprises an n-type silicon layer 11 and a p-type silicon layer 12, and a silicon nitride layer 13 is formed on the n-type silicon layer 11. Besides, a recess 19 is formed in the surfaces of the silicon nitride layer 13 and the n-type silicon layer 11, wherein the recess 19 penetrates the silicon nitride layer 13. Then, as shown in FIG. 1B, a silver paste layer 15 is formed in the recess 19 of the n-type silicon layer 11 by a printing method, and an aluminum paste layer 14 is formed on the p-type silicon layer 12. Finally, as shown in FIG. 1C, nickel layers 17 and 16 are formed respectively on the silver paste layer 15 and the aluminum paste layer 14 by an electroplating method or an electroless plating method. In the prior arts, two transferring printing steps that forms a silver paste layer 15 and an aluminum paste layer 14, and an electroplating step or an electroless step are usually comprised in the forming of the positive/negative electrodes.

With regards to the preparation of electrodes of solar cells, in the U.S. Pat. No. 5,591,565, a method of fabricating a negative electrode of the solar cell is proposed, in which a silver paste is used. Also, in the US 2008/035489, a method of fabricating an electrode of the solar cell by electroplating is used, in which a silver layer is formed on a silver paste layer by an electroplating method, and therefore a negative electrode is formed. In the TW 2008/18526, a patterned positive electrode structure of the solar cell is disclosed.

In the US 2009/239330(WO 2009/117007), a method of fabricating a solar cell by coating the silicon substrates with nano-particles is proposed, in which the electrode is made of a silver paste instead of being made by applying electroless plating on the surfaces of the silicon substrate.

It is well known that a silver paste, an aluminum paste, or a silver-aluminum paste can be applied to the manufacturing of the solar cell. For example, in the JP 2007/251609(TW 2009/26210), US 2009/0126797(TW200937451), and the US 2007/0215202 (TW200742098), the usage and the composition of the silver paste, the aluminum paste, and the silver-aluminum paste are detailedly described. However, since the cost of the silver paste is high, and the resistance of the glass powder and the polymers contained in the silver paste are both high (which may result in a high resistance of the electrode of the solar cell), the efficiency of the solar cell is reduced and the economical efficacy is lowered. Therefore, due to the low resistance of the nickel, it is proposed that nickel can be used to replace the silver paste in the forming of the electrode to lower the resistance and increase the efficiency of the solar cell.

The idea of using nickel for the manufacturing of the solar cell can be earlier seen in the U.S. Pat. No. 4,321,283, in which 640 g/L of nickel chloride and 40 g/L of ammonium fluoride is used in the nickel electroplating process for the surface of the silicone nitride-free solar cell silicon substrate to form electrodes.

In the US 2004/0005468, a method of fabricating an electrode of the solar cell is proposed, which comprises an activation step of the silicon substrate and a basic electroless nickel plating step.

In the WO 2009/070945, an illuminating method used for nickel electroplating to form the electrode of the solar cell is proposed, which is limited in the light source and therefore is inconvenient and slow compared with the method of the electroless plating.

Having high selectivity between silicon nitride and silicon for the electroless nickel plating solutions is important during the fabricating of the solar cells. If the selectivity between silicon nitride and silicon of the electroless nickel plating solutions is low, nickel will be formed on the silicon nitride layer and therefore resulted in the reducing of the active area and the reducing of the photoelectric conversion efficiency.

Accordingly, since a conventional electroless nickel plating solution is unable to satisfy sufficient selectivity between silicon nitride and silicon, the required structure for solar cell, in which no nickel is plated on the surface of the silicon nitride while the surface of the silicon is electroless plated with nickel, is difficult to obtain by using a conventional electroless nickel plating solution. Therefore, in the prior arts, although silver paste has low operability (i.e. workability) and costs high, it is selected without choice to form the negative electrode in the fabricating of the solar cells.

Therefore, it is desirable to provide an improved method of providing solar cell electrode to increase the photoelectric conversion efficiency of the solar cells, and lower the producing cost and simplify the manufacturing steps for the fabricating of the solar cells.

### SUMMARY OF THE INVENTION

The present invention provides a method of providing solar cell electrode by electroless plating, which comprises steps: (A) providing a silicon substrate having patterned surface comprising silicon and silicon nitride; (B) contacting the silicon substrate with an activator, wherein the activator comprises: a noble metal or a noble metal compound, a thickening agent, and water; (C) washing the silicon substrate by a cleaning agent; (D) dipping the silicon substrate in an electroless nickel plating solution to perform electroless plating and form a negative nickel electrode on the silicon layer of the first surface of the silicon substrate.

The method of providing solar cell electrode by electroless plating of the present invention may increase the differences of the absorbing ability between the silicon nitride and the silicon to the activator based on a sorting theory. Hence, the activation in the method of the present invention may provides a high selectivity between silicon nitride and silicon, and the working window for the process steps of the present method is large, stable, and tunable for surfaces with various conditions. Therefore, the method of providing solar cell electrode by electroless plating of the present invention enables the forming of electrodes without using a silver paste.

Specifically, according to the method of providing solar cell electrode by electroless plating of the present invention, in the step (A), i.e. in the term “providing a silicon substrate having a first surface and a second surface, wherein the first surface is a patterned surface comprising silicon and silicon nitride”, the patterned surface may be a plane surface comprising silicon and silicon nitride, a surface with elevation difference comprising silicon and silicon nitride in the micro-scale, or a texture surface comprising silicon and silicon nitride. Preferably, the patterned surface is one comprising silicon and silicon nitride, as shown in FIG. 2A. A silicon nitride layer 3 locates on a first surface 21 and an aluminum layer 6 locates on a second surface 22. Recesses 4 form in the silicon nitride layer 3 and in the first surface 21, and the recesses 4 extend through the silicon nitride layer 3 to expose the silicon surface 25 of the silicon layer 23. In addition, the silicon layer 23 may be a layer consisting of single crystal silicon, polycrystal silicon, microcrystal silicon, amorphous silicon, nano-sized single crystal silicon, or nano-sized polycrystal silicon.

As shown in FIG. 3A, according to the method of providing solar cell electrode by electroless plating of the present invention, in the step (A), the second surface 22 may be a silicon surface 26 without an aluminum layer being formed thereon. After the steps (A) to (D) are completed, a nickel layer 51 is formed in the recess 4 of the silicon substrate 2 (i.e. on the silicon surface 25), and a nickel layer 52 is formed on the second surface 22 of the silicon layer 24 (i.e. on the silicon surface 26), as shown in FIG. 3B. The silicon layer 24 (i.e. the second surface 22) may be a layer consisting of single crystal silicon, polycrystal silicon, microcrystal silicon, amorphous silicon, nano-sized single crystal silicon, or nano-sized polycrystal silicon.

According to the method of providing solar cell electrode by electroless plating of the present invention, in the step (A), the second surface is a patterned surface consisting of silicon and silicon oxide, silicon and silicon nitride, silicon and silicon oxynitride, silicon and organic polymer, or silicon and photoresist layer. As shown in FIG. 4A, a layer 31 containing recesses 5 is disposed on the second surface 22, and the recesses 5 extend through the layer 31 to expose the silicon surface 26 of the silicon layer 24 from the recesses 5. The silicon layer 24 (i.e. the silicon surface 26) may be a layer consisting of single crystal silicon, polycrystal silicon, microcrystal silicon, amorphous silicon, nano-sized single crystal silicon, or nano-sized polycrystal silicon. After the steps (A) to (D) are completed, a nickel layer 51 is formed in the recess 4 (i.e. on the silicon surface 25), and a nickel layer 52 is formed in the recess 5 (i.e. on the silicon surface 26), as shown in FIG. 4B. In addition, the layer 31 can be a silicon oxide layer, a silicon nitride layer, a silicon oxynitride layer, an organic polymer layer, a photoresist layer, or a combination thereof. Herein, the organic polymer layer, for example, can be a polyimide layer.

According to the method of providing solar cell electrode by electroless plating of the present invention, in the step (A), a patterned surface may further locate on the second surface, wherein the patterned surface consists of an aluminum layer and a silicon oxide layer, an aluminum layer and a silicon nitride layer, an aluminum layer and a silicon oxynitride layer, an aluminum layer and an organic polymer layer, or an aluminum layer and a photoresist layer. As shown in FIG. 5A, the layer 31 with the recesses 5 and an aluminum layer 7 formed in the recesses 5 are located on the second surface 22. After the steps (A) to (D) are completed, a nickel layer 51 is formed in the recess 4 (i.e. on the silicon surface 25), and a nickel layer 52 is formed on the aluminum layer 7, as shown in FIG. 5B. In addition, the layer 31 can be a silicon oxide layer, a silicon nitride layer, a silicon oxynitride layer, an organic polymer layer, a photoresist layer, or a combination thereof. Herein, the organic polymer layer, for example, can be a polyimide layer.

According to the method of providing solar cell electrode by electroless plating of the present invention, in the step (A), if it is not desired to plate Ni on the aluminum layer 6 (as shown in FIG. 2A) or on the second surface 22 (as shown in FIG. 3A), a silicon oxide layer, a silicon nitride layer, a silicon oxynitride layer, an organic polymer layer, or a photoresist layer is disposed on the aluminum layer 6 or on the second surface 22. As shown in FIG. 6A, in the case of a silicon substrate 2 without an aluminum layer, a layer 32 is disposed on the second surface 22, wherein the layer 32 may be a silicon oxide layer, a silicon nitride layer, a silicon oxynitride layer, an organic polymer layer, a photoresist layer, or a combination thereof. After the steps (A) to (D) are completed, a nickel layer 51 is only formed in the recess 4 (i.e. on silicon surface 25), as shown in FIG. 6B. Then, the layer 32 is removed through a conventional semiconductor manufacturing process. For example, the layer 32 can be removed by an organic solvent, a stripper, an etching solution, ionic plasma, or super critical fluid, as shown in FIG. 6C.

According to the method of forming electrodes of a solar cell by an electroless nickel plating process of the present invention, if it is desired to plate Ni on the second surface 22 and on the patterned surface consisting of silicon and silicon nitride sequentially, a layer 33 of an organic polymer layer or a photoresist layer can be first formed on the patterned surface consisting of silicon and silicon nitride, as shown in FIG. 7B. Next, the second surface 22 is plated with nickel, as shown in FIG. 7C. Then, the layer 33 of the organic polymer layer or the photoresist layer is removed by use of an organic solvent or a stripper, as shown in FIG. 7D, and a nickel layer 52 is formed on the second surface 22 of the silicon substrate 2. Finally, a negative electrode 51 is formed on the solar cell through the steps (B) to (D), as shown in FIG. 7E.

According to the method of providing solar cell electrode by electroless plating of the present invention, a silicon substrate 2 shown in FIG. 8A can be used in the step (A). As shown in FIG. 8A, a silicon substrate 2 is provided, wherein recesses 4 are formed in the silicon nitride layer 3 and the first surface 21, and the recesses 4 extend through the silicon nitride layer 3 to expose the silicon surface 25. Also, recesses 5 are formed in the layer 31 of silicon oxide, silicon nitride, silicon oxynitride and the second surface 22, and the recesses 5 penetrate the layer 31 to expose the surface 26 of the silicon layer 24. Then, nano-sized silicon particles containing n-type dopants are formed in the recesses 4, and nano-sized silicon particles containing p-type dopants are formed in the recesses 5, through a coating process or an inkjet printing process. After a sintering process, an n-type nano-sized silicon particle layer 71 and a p-type nano-sized silicon particle layer 72 are formed in the recesses 4 and the recesses 5 respectively, as shown in FIG. 8B. Finally, the steps (B) to (D) of the electroless nickel plating process are performed, and nickel layers 51, 52 are formed on the n-type nano-sized silicon particle layer 71 and the p-type nano-sized silicon particle layer 72 respectively.

According to the method of providing solar cell electrode by electroless plating of the present invention, in the step (B), the activator comprises: a noble metal or a noble metal compound, a thickening agent, and water, wherein the noble metal is preferably selected from the group consisting of: palladium, gold, silver, platinum, and a combination thereof; and the noble metal compound is preferably selected from the group consisting of: a palladium compound, a gold compound, a silver compound, a platinum compound, and a combination thereof. More preferably is a palladium compound, a gold compound, a silver compound, a platinum compound, and a combination thereof. Most preferably is a platinum compound, a gold compound, and a combination thereof. For example, the noble metal compound may be palladium chloride, palladium sulfate, palladium nitrate, palladium tetrammine chloride, gold chloride, or a combination thereof. The content of the noble metal may be preferably 1 mg/L to 500 mg/L, more preferably 10 mg/L to 300 mg/L.

In the present invention, the thickening agent in the step (B) is used to increase the viscosity of the activator, and enables the sorting process performing by washing at the step (C). That is, the thickening agent enables the activator to stay on the silicon surface, and simultaneously removes the activator locating on the silicon nitride. Therefore, the thickening agent may increase the difference between the abilities of electroless plating to the silicon and the silicon nitride, and increase the electroless plating selectivity between silicon nitride and silicon.

In the present invention, the thickening agent is not specially limited, as long as it can increase the viscosity and is able to mix with noble metal or noble metal compounds uniformly. The thickening agent is preferably water soluble due to the solubility to water of the noble metal compounds. For example, the thickening agent may be one selected from the group consisting of: polyol, saccharide, polyethylene glycol (PEG), polyvinyl pyrrolidone, polyacrylic acid, cellulose, and a combination thereof. The polyol may be preferably selected from the group consisting of: ethylene glycol, propylene glycol, glycerin (glycerol), mannitol, polyvinyl alcohol, and a combination thereof. The saccharide may be preferably selected from the group consisting of: glucose, fructose, sucrose, maltose, lactose, starch, and a combination thereof. The cellulose may be preferably selected from the group consisting of: carboxymethyl cellulose (CMC), hydroethyl cellulose (HEC), hydroxypropyl cellulose (HPC), hydroxypropyl methylcellulose (HPMC), ethyl cellulose (EC), and a combination thereof. The content of the thickening agent is preferably 0.05 g/L to 15 g/L, which may be adjusted according to the characteristic of the thickening agent and the sorting ability to the target.

In the present invention, the water in the step (B) is used as the solvent of the noble metal compounds and the thickening agent. Besides, if the solubility of the thickening agent to water is not enough, an organic solvent may be added to increase the solubility. The organic solvent used herein may be ethanol, propanol, isopropanol, acetone, butanone, alcohol ether, ethylene glycol monomethyl ether (EGME), ethylene glycol butyl ether, propylene glycol methyl ether (PGME), propanediol butyl ether, tetrahydrofuran (THF), N-methylpyrrolidinone (NMP), or a combination thereof.

In the present invention, in the step (B), the silicon substrate may preferably be dipped in the activator or sprayed with the activator to contact with the activator. When the silicon substrate is sprayed with the activator to contact with the activator, the opposite surfaces of the silicon substrate may be sprayed with the activators with the same or different concentrations; or the opposite surfaces of the silicon substrate may be sprayed with different activators (i.e. activators have different content). For example, an activator having palladium may be sprayed on one surface of the silicon substrate and an activator having gold may be sprayed on the other surface of the silicon substrate. Alternatively, the opposite surfaces of the silicon substrate may be sprayed with the activator simultaneously or sequentially (i.e. one surface of the silicon substrate is sprayed first and the other surface is sprayed later).

In the present invention, in the step (C), the cleaning agent used to wash the silicon substrate may be water or organic solvents. The cleaning agent should have desired solubility to the thickening agent to enhance the sorting ability. When a water-soluble solvent is used as the thickening agent, water can be used as the cleaning agent. If the solubility of the thickening agent to water is low, an organic solvent can be added to assist the washing process. Herein, the organic solvent may be ethanol, propanol, isopropanol, acetone, butanone, alcohol ether, ethylene glycol monomethyl ether (EGME), ethylene glycol butyl ether, propylene glycol methyl ether (PGME), propanediol butyl ether, tetrahydrofuran (THF), N-methylpyrrolidinone (NMP), or a combination thereof.

In the present invention, in the step (C), the washing step may be: dipping the silicon substrate in the cleaning agent; spraying the cleaning agent on the silicon substrate; dipping the silicon substrate in a flowing cleaning agent; or flowing (or showering) water on the first surface of the silicon substrate then followed with flowing (or showering) water on the second surface of the silicon substrate. The spraying may be performed on the two surfaces simultaneously or sequentially, and the spraying duration time for the two surfaces may be different. The washing time may be adjusted depending on the composition of the activator, the washing methods, the pattern of the silicon substrate, or the surface condition of the silicon substrate.

According to the method of providing solar cell electrode by electroless plating of the present invention, in the step (D), the electroless nickel plating solution may comprises: (a) 4.5 g/L to 10.0 g/L of nickel ions; (b) 0.5 g/L to 40 g/L of a reducing agent; (c) 30 g/L to 60 g/L of a first chelating agent selected from the group consisting of: citric acid, ammonium citrate, sodium citrate, potassium citrate, and a mixture thereof; (d) 5 g/L to 80 g/L of a second chelating agent selected from the group consisting of: alkylol amine, ethylene diamine, diethylene triamine, triethylene tetramine, and a combination thereof; (e) 0.0005 g/L to 0.002 g/L of a stabilizer; and (f) water.

According to the method of providing solar cell electrode by electroless plating of the present invention, the source of the nickel ion in the electroless nickel plating solution is preferably selected from the group consisting of: nickel chloride, nickel sulfate, nickel methane sulfonate, nickel aminosulfonate, and a combination thereof. The content of the nickel ion is preferably 4.5 to 10.0 g/L, or is equivalent to 20-45 g/L in the form of nickel sulfate hexahydrate, 18-40 g/L in the form of nickel chloride hexahydrate, 19-42.5 g/L in the form of nickel methane sulfonate, or 24.5-55 g/L in the form of nickel aminosulfonate(tetrahydrate).

According to the method of providing solar cell electrode by electroless plating of the present invention, the reducing agent of the electroless nickel plating solution is preferably selected from the group consisting of: sodium hypophosphite, ammonium hypophosphite, phosphinic acid, hydrazine, sodium borohydride (SBH), dimethyl amine borane (DMAB), diethylamine borane, morpholine borane, and a combination thereof.

According to the method of providing solar cell electrode by electroless plating of the present invention, the second chelating agent of the electroless nickel plating solution is preferably one selected from the group consisting of: alkylol amine (i.e. alcohol amine), ethylene diamine, diethylene triamine, triethylene tetramine, and a combination thereof. Herein, the alkylol amine (i.e. alcohol amine) is preferably selected from the group consisting of: diethanol amine, triethanol amine, and mixtures thereof.

According to the method of providing solar cell electrode by electroless plating of the present invention, the stabilizer may be preferably selected from the group consisting of: thiourea; derivatives of thiourea; thiocyanate; acetic compounds of Pb²⁺, Sb³⁺, and Bi³⁺; nitric compounds of Pb²⁺, Sb³⁺, and Bi³⁺; and water-soluble organic material with —SH group.

According to the method of providing solar cell electrode by electroless plating of the present invention, in the step (D), the electroless nickel plating solution may further comprise a buffering agent, which can be selected from the group consisting of: ammonium chloride, ammonium sulfate, boric acid, acetic acid, propanoic acid, oxalic acid, succinic acid, lactic acid, glycolic acid, tartaric acid, and a combination thereof. Preferably, the content of the buffering agent is 1 g/L to 20 g/L. The buffering agent may smooth the deviation of the pH value during operation and therefore keep the solution in a stable state.

According to the method of providing solar cell electrode by electroless plating of the present invention, in the step (D), the electroless nickel plating solution may further comprise an accelerating agent, which may be selected from the group consisting of: hydrofluoric acid (HF), sodium fluoride (NaF), potassium fluoride (KF), ammonium fluoride (NH₄F), and a combination thereof. Preferably, the content of the accelerating agent is 2 g/L to 12 g/L.

According to the method of providing solar cell electrode by electroless plating of the present invention, when an aluminum layer is disposed on the second surface of the silicon substrate, in the step (D), the concentration of the chloride ion in the electroless nickel plating solution is preferably less than 1000 ppm, in order to avoid corrosion of the aluminum layer.

According to the method of providing solar cell electrode by electroless plating of the present invention, in the step (D), the electroless nickel plating solution may further comprise two kinds of reducing agents (i.e. a first reducing agent and a second reducing agent). The first reducing agent is preferably selected from the group consisting of: sodium hypophosphite, ammonium hypophosphite, phosphinic acid, and a combination thereof; and the second reducing agent is borane, which is preferably selected from the group consisting of: sodium borohydride (SBH), dimethylamine borane (DMAB), diethylamine borane, morpholine borane, and a combination thereof. For example, the electroless nickel plating solution may further comprise sodium hypophosphate as a first reducing agent and borane as a second reducing agent. For example, the electroless nickel plating solution may comprise 5 g/L to 30 g/L of sodium hypophosphate as a first reducing agent and 0.5 g/L to 20 g/L of dimethylamine borane (DMAB) as a second reducing agent.

According to the method of providing solar cell electrode by electroless plating of the present invention, in the step (D), the pH value of the electroless nickel plating solution is preferably in a range of 7.0 to 10.0. The pH value of the electroless nickel plating solution is preferably in a range of 7.0 to 9.0 when an aluminum layer is formed on the silicon substrate. If the pH value is too high, the aluminum layer may be corroded. Herein, the pH adjusting agent may be selected from the group consisting of: ammonia, sodium hydroxide (NaOH), potassium hydroxide (KOH), and a combination thereof.

In the present invention, the electroless nickel plating solution is preferably operated in a temperature range of 40° C. to 80° C.

According to the method of providing solar cell electrode by electroless plating of the present invention, a step may be preferably comprised between the steps (A) and (B): removing the silicon oxide on the silicon substrate. For example, the silicon substrate is dipped into the 0.1% to 5% of hydrofluoric acid to remove a trace of oxide layer on the silicon surface 25 of the recesses 4, as shown in 2A, and then the silicon surface 25 is washed with water to remove the hydrofluoric acid on the silicon surface 25.

The present invention also provides an activator for forming an electrode of a solar cell having patterned structure comprising silicon and silicon nitride, wherein the activator comprises: (a) a noble metal or a noble metal compound, (b) a thickening agent, and (c) water.

The activator of the present invention can be used in the formation of an electrode of a solar cell to provide proper selectivity between silicon nitride and silicon for the electroless nickel plating solutions.

Accordingly to the activator of the present invention, the content of the noble metal or the noble metal compound is preferably 1 mg/L to 500 mg/L, and the content of the thickening agent is preferably 0.05 g/L to 15 g/L.

Accordingly to the activator of the present invention, the noble metal is preferably selected from the group consisting of: palladium, gold, silver, platinum, and a combination thereof; and the noble metal compound is preferably selected from the group consisting of: a palladium compound, a gold compound, a silver compound, a platinum compound, and a combination thereof. More preferably a palladium compound, a gold compound, a silver compound, a platinum compound, or a combination thereof is used herein. Most preferably a platinum compound, a gold compound, or a combination thereof is used herein.

Accordingly to the activator of the present invention, the thickening agent may be one selected from the group consisting of: polyol, saccharide, polyethylene glycol (PEG), polyvinyl pyrrolidone, polyacrylic acid, cellulose, and a combination thereof.

Accordingly to the activator of the present invention, the polyol may be preferably selected from the group consisting of: ethylene glycol, propylene glycol, glycerin (glycerol), mannitol, polyvinyl alcohol, and a combination thereof.

Accordingly to the activator of the present invention, the saccharide may be preferably selected from the group consisting of: glucose, fructose, sucrose, maltose, lactose, starch, and a combination thereof.

Accordingly to the activator of the present invention, the cellulose may be preferably selected from the group consisting of: carboxymethyl cellulose (CMC), hydroethyl cellulose (HEC), hydroxypropyl cellulose (HPC), hydroxypropyl methylcellulose (HPMC), ethyl cellulose (EC), and a combination thereof.

### BRIEF DESCRIPTION OF THE DRAWINGS

FIGS. 1A-1C are cross-sectional views illustrating a conventional process for forming electrodes of a solar cell; and

FIGS. 2A-2B, 3A-3B, 4A-4B, 5A-5B, 6A-6C, 7A-7E, and 8A-8C are cross-sectional views illustrating processes for forming electrodes of a solar cell by use of the method of forming electrodes of a solar cell by an electroless nickel plating process of the present invention.

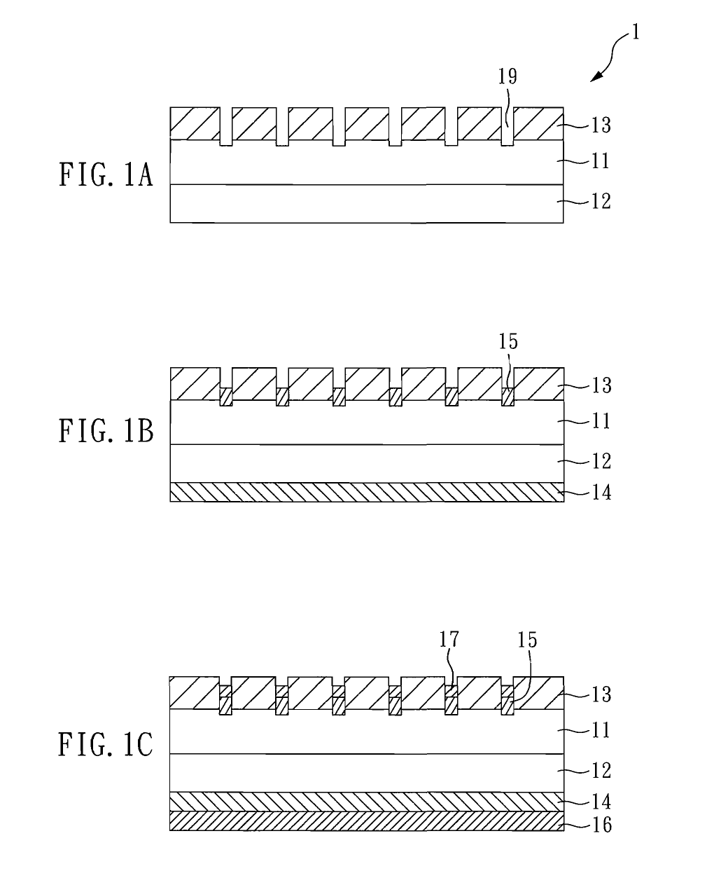

### DETAILED DESCRIPTION OF THE PREFERRED EMBODIMENT

Because of the specific embodiments illustrating the practice of the present invention, a person having ordinary skill in the art can easily understand other advantages and efficiency of the present invention through the content disclosed therein. The present invention can also be practiced or applied by other variant embodiments. Many other possible modifications and variations of any detail in the present specification based on different outlooks and applications can be made without departing from the spirit of the invention.

### Example 1-1

### Preparation of the Activator

The activators A to D are prepared as the compositions and methods shown below.

Activator A: 100 mg/L of palladium chloride and 1 g/L of ethylene glycol is dissolved in water to give 1 L of activator A.

Activator B: 50 mg/L of palladium chloride and 0.5 g/L of glycerin is dissolved in water to give 1 L of activator B.

Activator C: 250 mg/L of palladium chloride and 1 g/L of polyvinyl pyrrolidone (K30) is dissolved in water to give 1 L of activator C.

Activator D: 10 mg/L of palladium chloride and 1 g/L of polyethylene glycol (PEG4000) is dissolved in water to give 1 L of activator D.

### Example 1-2

### Preparation of the Electroless Nickel Plating Solution

Electroless nickel plating solutions A to E are prepared as the compositions and methods shown below.

<Electroless Nickel Plating Solution A>

34 g/L of nickel sulfate, 18 g/L of sodium hypophosphate, 50 g/L of ammonium citrate, 8 g/L of ammonium chloride, 10 g/L of triethanolamine, 4 g/L of sodium fluoride, and 0.0009 g/L of thiourea is dissolved in water to give 1 L of solution. The pH value of the solution is then adjusted to 7.5 to 8.2 to obtain the electroless nickel plating solution A.

<Electroless Nickel Plating Solution B>

34 g/L of nickel chloride, 7 g/L of DMAB (dimethylamine borane), 50 g/L of ammonium citrate, 8 g/L of ammonium chloride, 60 g/L of triethanolamine, 8 g/L of sodium fluoride, 0.001 g/L of thiourea, and 1 g/L of saccharin is dissolved in water to give 1 L of solution. The pH value of the solution is then adjusted to 8.0 to 9.0 to obtain the electroless nickel plating solution B.

<Electroless Nickel Plating Solution C>

35 g/L of nickel sulfate, 15 g/L of sodium hypophosphite, 5 g/L of DMAB (dimethylamine borane), 40 g/L of ammonium citrate, 5 g/L of ammonium sulfate, 20 g/L of triethanolamine, 6 g/L of sodium fluoride, and 0.001 g/L of Pb²⁺ is dissolved in water to give 1 L of solution. The pH value of the solution is then adjusted to 8.0 to 8.5 to obtain the electroless nickel plating solution C.

<Electroless Nickel Plating Solution D>

34 g/L of nickel chloride; 18 g/L of sodium hypophosphate; 50 g/L of ammonium citrate; 8 g/L of ammonium chloride; 30 g/L of triethanolamine; 7 g/L of sodium fluoride; 0.001 g/L of thiourea; and 1 g/L of saccharin is dissolved in water to give 1 L of solution. The pH value of the solution is then adjusted to 8.0 to 9.0 to obtain the electroless nickel plating solution D.

<Electroless Nickel Plating Solution E>

35 g/L of nickel sulfate, 25 g/L of sodium hypophosphite, 1.25 g/L of DMAB (dimethylamine borane), 55 g/L of ammonium citrate, 13 g/L of ammonium sulfate, 40 g/L of triethanolamine, 5 g/L of sodium fluoride, and 0.001 g/L of Pb²⁺ is dissolved in water to give 1 L of solution. The pH value of the solution is then adjusted to 8.5 to 9.3 to obtain the electroless nickel plating solution E.

### Example 1-3

### Preparation of the Electrode of the Solar Cell by Electroless Plating

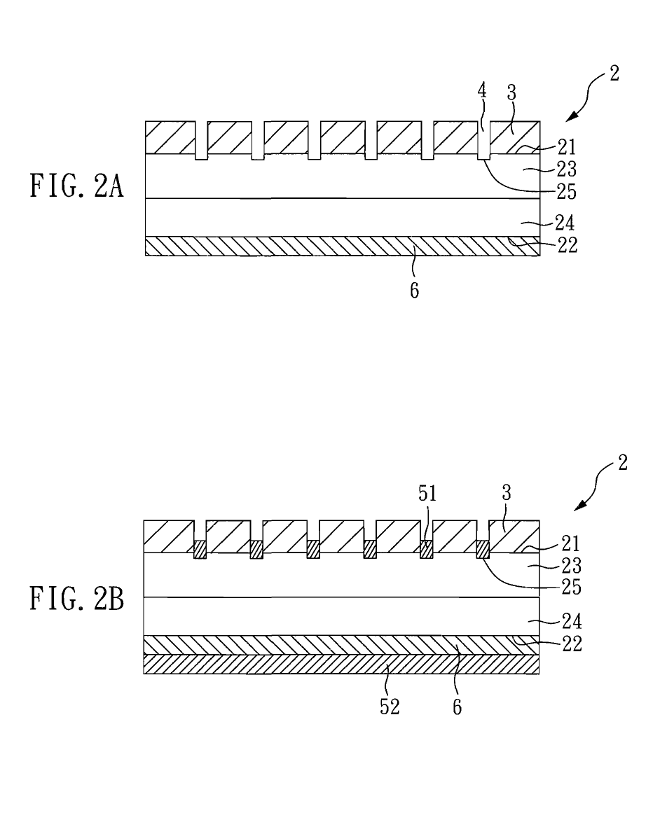

First, as shown in FIG. 2A, a silicon substrate 2 is provided, which has a first surface 21 and a second surface 22. The first surface 21 has an n-type silicon layer 23, and the second surface 22 has a p-type silicon layer 24. A silicon nitride layer 3 locates on the first surface 21 and an aluminum layer 6 locates on the second surface 22. Recesses 4 are formed in the silicon nitride layer 3 and in the first surface 21, and the recesses 4 extend through the silicon nitride layer 3.

Then, the silicon substrate 2 having a silicon nitride layer 3 and an aluminum layer 6 is dipped in the activator A provided by the example 1-1. After taken out from the activator A, the silicon substrate 2 is then washed for 4 minutes by dipping in flowing water.

Then, the silicon substrate 2 is dipped in the electroless nickel plating solution A provided from the example 1-2 (with a temperature of 50° C.) to perform an electroless nickel plating process for 10 minutes to form a negative electrode 51 and a positive electrode 52 in the recess 4 of the silicon substrate 2 (i.e. on the silicon surface 25) and on the surface of the aluminum layer 6 respectively, as shown in FIG. 2B. Therefore, electrodes of a solar cell made by an electroless nickel plating method is obtained.

### Example 2

### Preparation of the Electrode of the Solar Cell by Electroless Plating

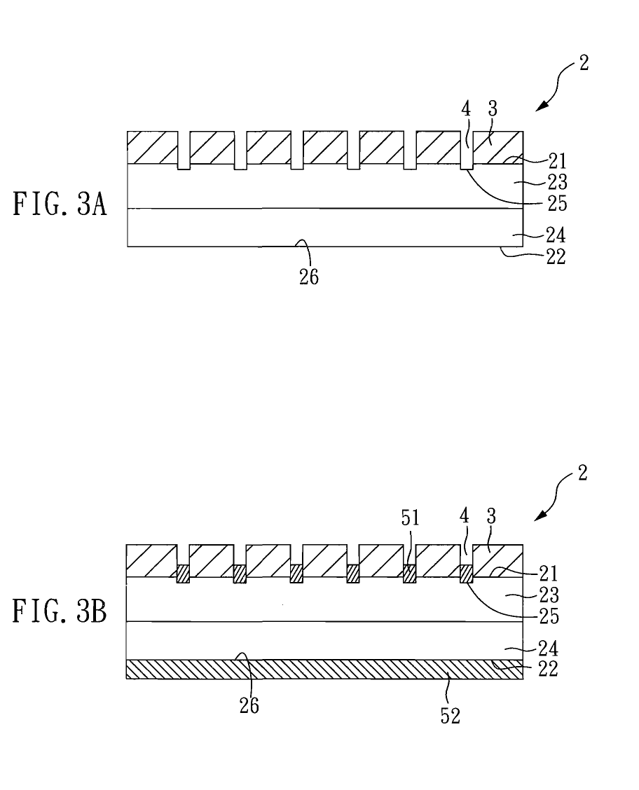

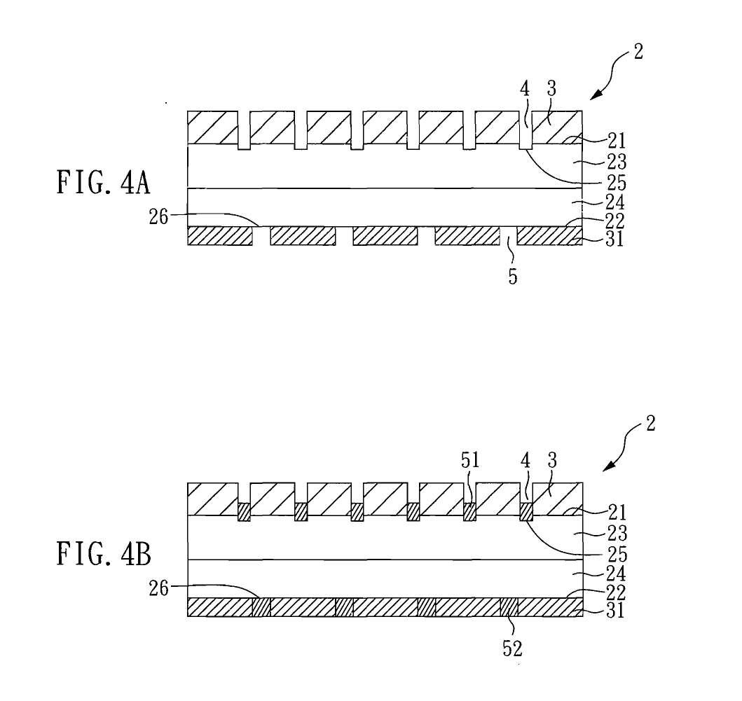

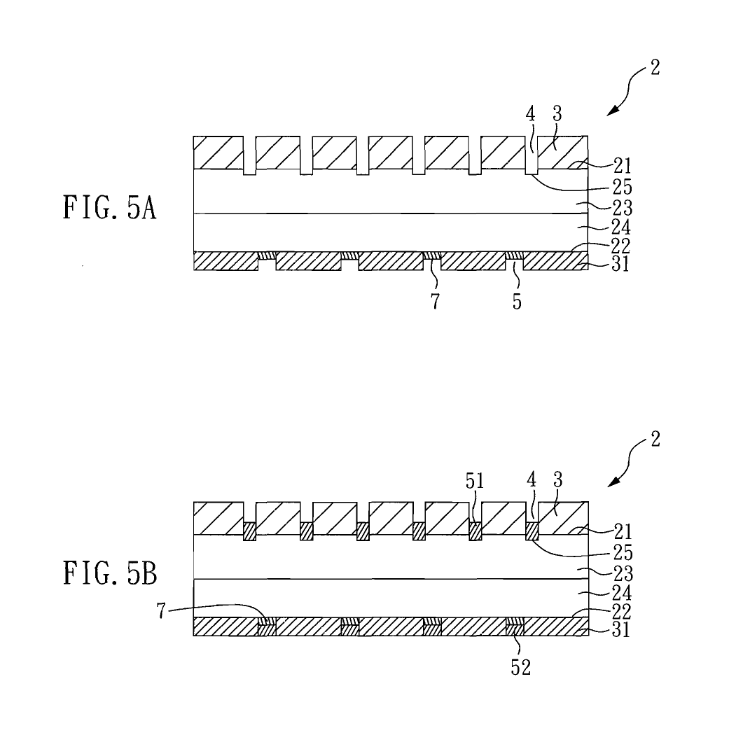

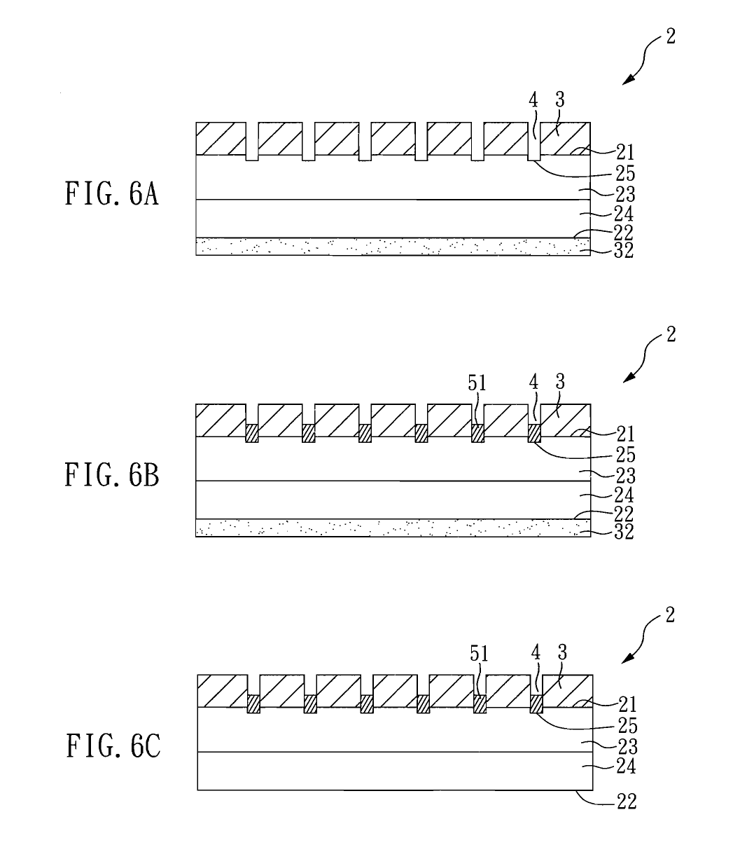

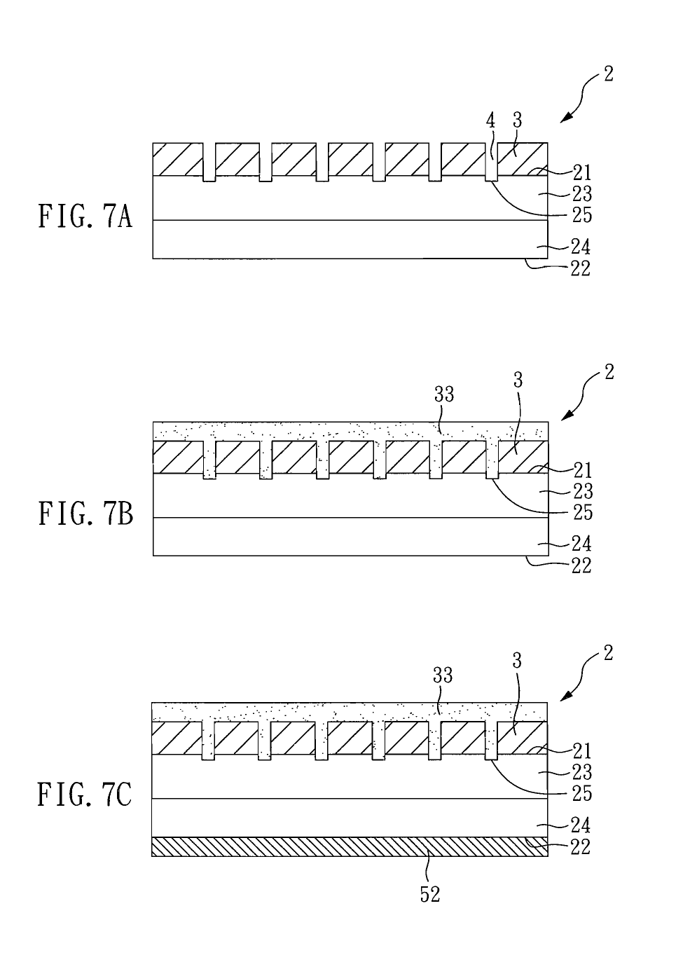

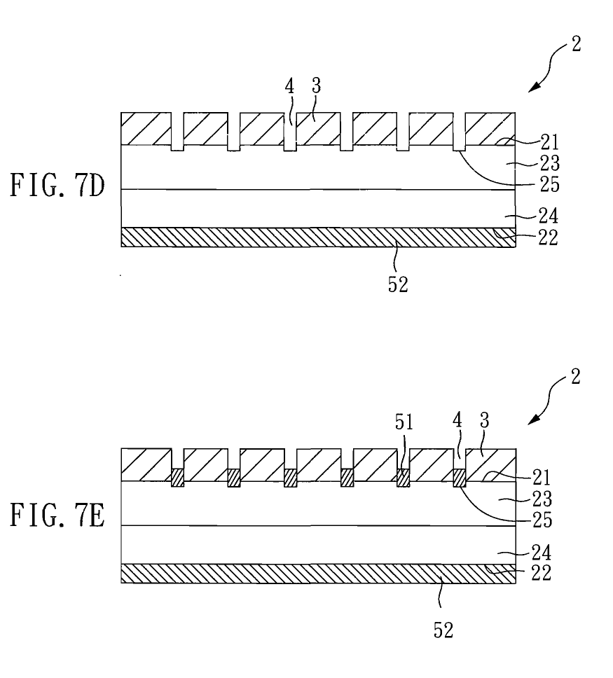

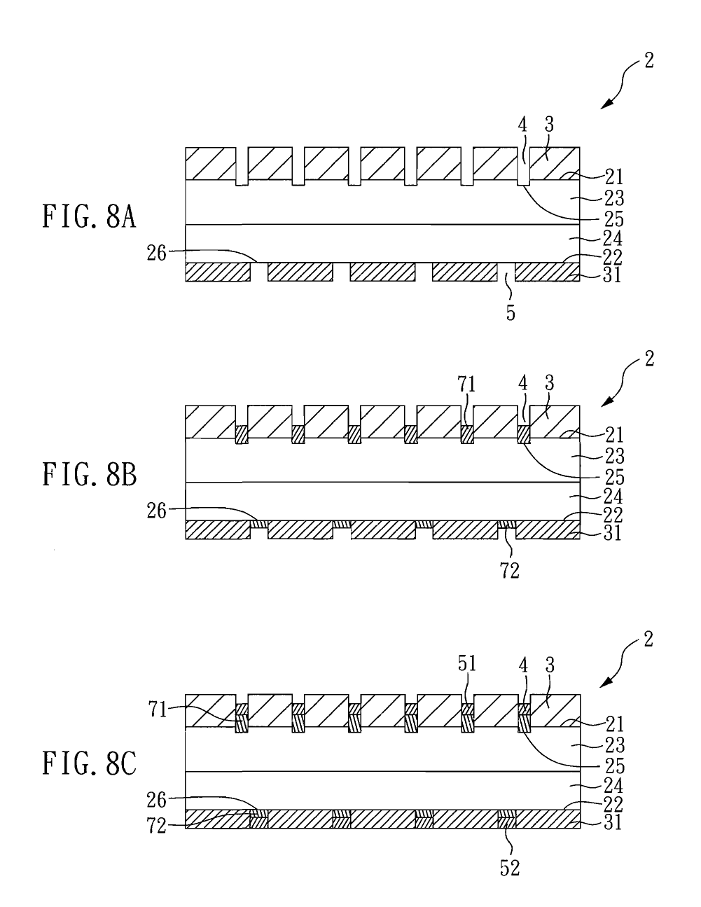

First, as shown in FIG. 3A, a silicon substrate 2 is provided, which has a first surface 21 and a second surface 22. The first surface 21 has an n-type silicon layer 23, and the second surface 22 has a p-type silicon layer 24. A silicon nitride layer 3 locates on the first surface 21. Recesses 4 are formed in the silicon nitride layer 3 and in the first surface 21, and the recesses 4 extend through the silicon nitride layer 3 to expose the silicon surface 25.

Then, the silicon substrate 2 having a silicon nitride layer 3 is dipped in 1 wt % of hydrofluoric acid for 20 seconds to perform a removing silicon oxide process and subsequently followed with cleaning by water.

Next, the silicon substrate 2 is cleaned by the hydrofluoric acid, and then the silicon substrate 2 is dipped in the activator A provided by the example 1-1. After taken out from the activator A, the silicon substrate 2 is then washed for 5 minutes by dipping in flowing water.

Then, the silicon substrate 2 is dipped in the electroless nickel plating solution C prepared in the example 1-2 (the temperature is 60° C. to 65° C.) to perform an electroless nickel plating process for 10 minutes to form a negative electrode 51 and a positive electrode 52 in the recess 4 of the silicon substrate 2 and on the second surface 22 respectively, as shown in FIG. 3B. Therefore, electrodes of a solar cell made by an electroless nickel plating method is obtained.

### Example 3

### Preparation of the Electrode of the Solar Cell by Electroless Plating

First, as shown in FIG. 2A, a silicon substrate 2 is provided, which has a first surface 21 and a second surface 22. The first surface 21 has an n-type silicon layer 23, and the second surface 22 has a p-type silicon layer 24. A silicon nitride layer 3 locates on the first surface 21 and an aluminum layer 6 locates on the second surface 22. Recesses 4 are formed in the silicon nitride layer 3 and in the first surface 21, and the recesses 4 extend through the silicon nitride layer 3.

Then the silicon substrate 2 having a silicon nitride layer 3 is dipped in the activator B provided by the example 1-1. After taken out from the activator B, the silicon substrate 2 is then washed for 10 minutes by dipping in flowing water.

Next, the silicon substrate 2 is dipped in the electroless nickel plating solution B prepared in the example 1-2 (the temperature is 57° C.) to perform an electroless nickel plating process for 3 minutes to form a negative electrode 51 and a positive electrode 52 in the recess 4 of the silicon substrate 2 (i.e. on the silicon surface 25) and on the surface of the aluminum layer 6 respectively, as shown in FIG. 2B. Then, the silicon substrate 2 is cleaned with water.

Then, the silicon substrate 2 is dipped in the electroless nickel plating solution A prepared in the example 1-2 (the temperature is 57° C.) to perform a second electroless nickel plating process for 7 minutes to thicken the negative electrode 51 and the positive electrode 52 of the silicon substrate 2. Therefore, electrodes of a solar cell made by an electroless nickel plating method is obtained.

Although the present invention has been explained in relation to its preferred embodiment, it is to be understood that many other possible modifications and variations can be made without departing from the spirit and scope of the invention as hereinafter claimed.

What is claimed is:

1. A method of providing solar cell electrode by electroless plating, which comprises steps:
(A) providing a silicon substrate having patterned surface comprising silicon and silicon nitride;
(B) contacting the silicon substrate with an activator, wherein the activator comprises: a noble metal or a noble metal compound, a thickening agent, and water;
(C) washing the silicon substrate by a cleaning agent; and
(D) dipping the silicon substrate in an electroless nickel plating solution to perform electroless plating and form a negative nickel electrode on the silicon layer of the first surface of the silicon substrate.

2. The method of providing solar cell electrode by electroless plating as claimed in claim 1, wherein the noble metal is selected from the group consisting of: palladium, gold, silver, platinum, and a combination thereof; and the noble metal compound is selected from the group consisting of: a palladium compound, a gold compound, a silver compound, a platinum compound, and a combination thereof.

3. The method of providing solar cell electrode by electroless plating as claimed in claim 1, wherein the content of the noble metal or the noble metal compound is 1 mg/L to 500 mg/L.

4. The method of providing solar cell electrode by electroless plating as claimed in claim 1, wherein the thickening agent is selected from the group consisting of: polyol, saccharide, polyethylene glycol, polyvinyl pyrrolidone, polyacrylic acid, cellulose, and a combination thereof.

5. The method of providing solar cell electrode by electroless plating as claimed in claim 4, wherein the polyol is selected from the group consisting of: ethylene glycol, propylene glycol, glycerin, mannitol, polyvinyl alcohol, and a combination thereof.

6. The method of providing solar cell electrode by electroless plating as claimed in claim 4, wherein the cellulose is selected from the group consisting of: carboxymethyl cellulose, hydroethyl cellulose, hydroxypropyl cellulose, hydroxypropyl methylcellulose, ethyl cellulose, and a combination thereof.

7. The method of providing solar cell electrode by electroless plating as claimed in claim 4, wherein the saccharide is selected from the group consisting of: glucose, fructose, sucrose, maltose, lactose, starch, and a combination thereof.

8. The method of providing solar cell electrode by electroless plating as claimed in claim 1, wherein the content of the thickening agent is 0.05 g/L to 15 g/L.

9. The method of providing solar cell electrode by electroless plating as claimed in claim 1, wherein in the step (B), the silicon substrate is dipped in or sprayed with the activator to contact with the activator.

10. The method of providing solar cell electrode by electroless plating as claimed in claim 1, wherein in the step (C), the silicon substrate is washed by dipped in, sprayed with, or showered with the cleaning agent.

11. The method of providing solar cell electrode by electroless plating as claimed in claim 1, wherein the electroless nickel plating solution comprises: (a) 4.5 g/L to 10.0 g/L of nickel ions; (b) 0.5 g/L to 40 g/L of a reducing agent; (c) 30 g/L to 60 g/L of a first chelating agent selected from the group consisting of: citric acid, ammonium citrate, sodium citrate, potassium citrate, and a mixture thereof; (d) 5 g/L to 80 g/L of a second chelating agent selected from the group consisting of: alkylol amine, ethylene diamine, diethylene triamine, triethylene tetramine, and a combination thereof; (e) 0.0005 g/L to 0.002 g/L of a stabilizer; and (f) water.

12. The method of providing solar cell electrode by electroless plating as claimed in claim 11, wherein the alkylol amine is selected from the group consisting of: diethanol amine, triethanol amine, and mixtures thereof.

13. The method of providing solar cell electrode by electroless plating as claimed in claim 1, wherein in the step (D), the content of the chloride ion in the electroless nickel plating solution is less than 1000 ppm.

14. The method of providing solar cell electrode by electroless plating as claimed in claim 1, wherein in the step (D), the electroless nickel plating solution further comprises: a first reducing agent, which is selected from the group consisting of sodium hypophosphate, ammonium hypophosphite, phosphinic acid, and a mixture thereof; and a second reducing agent, which is borane.

15. The method of providing solar cell electrode by electroless plating as claimed in claim 1, wherein in the step (D), the pH value of the electroless nickel plating solution is in a range of 7.0 to 10.0.

16. The method of providing solar cell electrode by electroless plating as claimed in claim 1, wherein in the step (D), the electroless nickel plating is performed at 40° C. to 80° C.

17. The method of providing solar cell electrode by electroless plating as claimed in claim 11, wherein the reducing agent of the electroless nickel plating solution is selected from the group consisting of: sodium hypophosphite, ammonium hypophosphite, phosphinic acid, hydrazine, sodium borohydride, dimethylamine borane diethylamine borane, morpholine borane, and a combination thereof.

18. The method of providing solar cell electrode by electroless plating as claimed in claim 11, wherein the electroless nickel plating solution further comprises a buffering agent, which is selected from the group consisting of: ammonium chloride, ammonium sulfate, boric acid, acetic acid, propanoic acid, oxalic acid, succinic acid, lactic acid, glycolic acid, tartaric acid, and a combination thereof, and the content of the buffering agent is 1 g/L to 20 g/L.

19. The method of providing solar cell electrode by electroless plating as claimed in claim 11, wherein the electroless nickel plating solution further comprises an accelerating agent selected from the group consisting of: hydrofluoric acid, sodium fluoride, potassium fluoride, ammonium fluoride, and a combination thereof, and the content of the accelerating agent is 2 to 12 g/L.

20. The method of providing solar cell electrode by electroless plating as claimed in claim 11, wherein the stabilizer is selected from the group consisting of: thiourea; derivatives of thiourea; thiocyanate; acetic compounds of Pb²⁺, Sb³⁺, and Bi³⁺; nitric compounds of Pb²⁺, Sb³⁺, and Bi³⁺; and water-soluble organic material with —SH group.

21. An activator for forming an electrode of a solar cell having patterned structure comprising silicon and silicon nitride, comprising: (a) a noble metal or a noble metal compound, (b) a thickening agent, and (c) water.

22. The activator as claimed in claim 21, wherein the content of the noble metal or the noble metal compound is 1 mg/L to 500 mg/L; and the content of the thickening agent is 0.05 g/L to 15 g/L.

23. The activator as claimed in claim 21, wherein the noble metal is selected from the group consisting of: palladium, gold, silver, platinum, and a combination thereof; and the noble metal compound is selected from the group consisting of: a palladium compound, a gold compound, a silver compound, a platinum compound, and a combination thereof.

24. The activator as claimed in claim 21, wherein the thickening agent is selected from the group consisting of: polyol, saccharide, polyethylene glycol, polyvinyl pyrrolidone, polyacrylic acid, cellulose, and a combination thereof.

25. The activator as claimed in claim 24, wherein the polyol is selected from the group consisting of: ethylene glycol, propylene glycol, glycerin, mannitol, polyvinyl alcohol, and a combination thereof.

26. The activator as claimed in claim 24, wherein the saccharide is selected from the group consisting of: glucose, fructose, sucrose, maltose, lactose, starch, and a combination thereof.

27. The activator as claimed in claim 24, wherein the cellulose is selected from the group consisting of: carboxymethyl cellulose, hydroethyl cellulose, hydroxypropyl cellulose, hydroxypropyl methylcellulose, ethyl cellulose, and a combination thereof.
